(19) United States
(12) Patent Application Publication
(10) Pub. No.: US 2025/0023330 A1
(43) Pub. Date: Jan. 16, 2025

(54) Double Waveguide Structure For Edge-Emitting Semiconductor Laser And Method Of Forming The Same

(71) Applicant: II-VI Delaware, Inc., Wilmington, DE (US)

(72) Inventors: Anissa Zeghuzi, Zurich (CH); Rene Todt, Spiez (CH)

(73) Assignee: II-VI Delaware, Inc., Wilmington, DE (US)

(21) Appl. No.: 18/221,103

(22) Filed: Jul. 12, 2023

(51) Int. Cl. H01S 5/22; H01S 5/20

(52) U.S. Cl. CPC H01S 5/22; H01S 5/205; H01S 2301/16

(57) ABSTRACT

An edge-emitting semiconductor laser and fabrication method is disclosed that includes a second, passive waveguide and cladding layer disposed above the multi-layer arrangement of a first waveguiding layer and a first cladding layer. The active region of the laser is contained within or along a lower surface of the first waveguiding layer, as in standard devices. The regrowth interface is located along a top surface of the first cladding layer, as compared to the prior art where this interface is located within the first waveguiding layer. The resulting configuration exhibits an improved coupling efficiency by maintaining the propagating optical mode within the active waveguiding layer and away from the regrowth interface.

### TECHNICAL FIELD

The present disclosure relates to an edge-emitting semiconductor laser and, more particularly, to the utilization of a double waveguide structure to improve the laser's high power performance in the presence of necessary levels of injection current.

### BACKGROUND

High power edge-emitting semiconductor lasers have become important components in various applications including high-power pump sources for doped fiber amplifiers, high-power cutting tools for machining purposes, high-power signal paths for free-space optical communication systems, and the like.

In most cases, features such as long lifetime, reliable and stable output, high output power, high electro-optic efficiency, and high beam quality are generally desirable. One key for the long-term reliability of such high power lasers is directly related to the stability of the laser facets cleaved to form the opposing mirrors of the laser cavity. Laser facet degradation is a complex reaction that can be driven by light, current, and heat, resulting in power degradation and, in severe cases, catastrophic optical damage (COD) to the mirror surfaces themselves.

In one approach to improve the integrity of the semiconductor laser structure, increased facet stability is provided by removing the active region material present along a longitudinal depth from the front facet (edge) of the structure (using an etching process, for example), followed by an epitaxial regrowth of a passive layer arrangement. As will be discussed in detail below, this regrown epitaxial mirror is often referred to as a “non-absorbing mirror” type of laser facet. Problems remain with the non-absorbing mirror, for example in terms of coupling efficiency between the unetched portion of the structure to etched, non-absorbing mirror portion or, alternatively, the regrowth interface may be located too close to the active region, resulting in high absorption and possibly COD (which is intended to be avoided in the first instance).

Other problems with the performance of high power edge-emitting lasers relate to the levels of injection current required to obtain the desired output power levels. The presence of the injected current is known to elevate the temperature in the localized area along the injection stripe, increasing the relative refractive index in the area of current injection by an amount sufficient to create a thermally-induced waveguide that is able to guide several lateral modes, degrading beam quality of the high power output beam.

### SUMMARY OF THE DISCLOSURE

Disclosed herein is a particular configuration of an edge-emitting semiconductor laser that provides the necessary protection for the facet of an edge-emitting semiconductor laser without influencing the optical coupling efficiency between the active and passive waveguiding portions of the structure or creating the potential for high absorption at the regrowth interface. The disclosed structure may be specifically tailored to compensate for the thermally-induced localized changes in refractive index and control the number of excited lateral modes.

In accordance with the teachings of this disclosure, an edge-emitting semiconductor laser is fabricated to include a second waveguiding layer and a second cladding layer that are disposed in sequence over an original cladding layer (typically, these are p-type layers). Once the first cladding layer has been formed (grown), a section of the structure is etched to define the non-absorbing mirror facet as with the prior art. The second waveguiding and cladding layers are then grown, forming an “unetched region” (defined at times as “epi I”) that includes a complete stack of the first and second waveguiding and cladding layers and an “etched region” (defined at times as “epi II”) that includes only the second waveguiding and cladding layers (no active region included along the second waveguiding layer). In one example embodiment, the epi II region may be used to form a non-absorbing mirror arrangement at a front (emitting) or rear facet of the edge-emitting semiconductor laser. In other example embodiment of a double waveguide laser structure, a pair of epi II structures may be disposed along lateral edges of a centrally-positioned injection stripe of an edge-emitting laser to minimize current spreading (without the need to create a ridge-type structure).

The combination of the original (first) waveguiding and cladding layers with the second (passive) waveguiding and cladding layers is often referred to at times below as a “double waveguide” structure. The active region of the laser is contained within or along a lower surface of the first waveguiding layer, as in standard devices. The regrowth interface in the disclosed structure is located between the first cladding layer and the second waveguiding layer, increasing (as compared to the prior art) the vertical separation between the propagating mode and the regrowth interface.

The vertical mode profile of the disclosed semiconductor laser may be tailored by controlling the properties of the original (first) waveguiding layer and associated cladding layer (e.g., thickness, composition, etc.) to ensure that the propagating optical mode exhibits a minimum value (essentially zero) along the regrowth interface within a defined interior region (referred to as the “epi I” area). Choosing appropriate parameters (e.g., thickness, composition, etc.) for the second waveguiding and cladding layers ensures efficient coupling of the propagating mode from the active epi I area into the adjacent non-absorbing mirror area (also referred to as the “epi II” area) along the facets.

Additionally, it is contemplated that the control of the thickness and composition of a pair of double waveguide structures may be included along opposing sides of injection stripe region may be used to control the number of lateral modes that are excited as a result of thermally-induced changes in refractive index along the injection stripe as described above. The composition and/or dimensions of the passive waveguiding and cladding layers creates a step change in the refractive index between the central, active waveguide and the side passive waveguides. The material choices create either a positive step index change across the lateral direction of the device (i.e., an anti-guiding configuration) or a negative step index change (a guiding configuration).

An example embodiment of the disclosure may take the form of an edge-emitting semiconductor laser comprising: a semiconductor substrate, a cladding layer of a first conductivity type formed on the semiconductor substrate, a waveguiding layer of the first conductivity type formed on the cladding layer, an active region disposed over a defined region of the waveguiding layer, a first waveguiding layer of a second, opposing conductivity type formed over the active region, a first cladding layer of the second conductivity type formed over the first waveguiding layer, where defined areas of the combination of the active region, the first waveguiding layer and the first cladding layer have been removed and defining a regrowth interface along surfaces of the waveguiding layer of the first conductivity type exposed by the removal. The laser structure further comprising a second waveguiding layer of the second conductivity type formed over the regrowth interface and a second cladding layer of the second conductivity type formed over the second waveguiding layer of the second conductivity type, wherein the composition and thicknesses of the first waveguiding and cladding layers of the second conductivity type are selected to create a defined separation between a propagating longitudinal optical mode and the regrowth interface.

Another embodiment may include a method of forming such a semiconductor laser as described above, including the steps of: providing a semiconductor substrate of a first conductivity type; forming, in sequence, a cladding layer of the first conductivity type and a waveguiding layer of the first conductivity type on the semiconductor substrate; forming an active region across a top surface of the first conductivity type waveguiding layer; forming, in sequence, a first waveguiding layer of a second, opposing conductivity type and a first cladding layer of the second, opposing conductivity type over the active region, the formed configuration defined as having a front facet and an opposing rear facet wherein upon activation an optical beam is emitted at least through the front facet; removing a combination of the active region, the first waveguiding layer and the first cladding layer from a portion of the formed configuration, an exposed surface formed by the removal defined as a regrowth interface; and forming, in sequence, a second waveguiding layer of the second conductivity type and a second cladding layer of the second conductivity type over the regrowth interface, selected to create a defined separation between a propagating longitudinal optical mode and the regrowth interface.

Other and further embodiments and aspects of this disclosure will become apparent during the course of the following discussion and by reference to the accompanying drawings.

### BRIEF DESCRIPTION OF THE DRAWINGS

Referring now to the drawings,

FIG. 1 illustrates a configuration of a prior art edge-emitting semiconductor laser subsequent to an initial epitaxial growth process;

FIG. 2 shows a following step in a fabrication process of the prior art laser of FIG. 1, illustrating the formation of recessed area along the front facet where a non-absorbing mirror may then be formed;

FIG. 3 illustrates a configuration of the prior art edge-emitting laser subsequent to an epitaxial regrowth process, including the formation of a non-absorbing mirror structure along the front facet region;

FIG. 4 is a lateral view of the prior art edge-emitting laser of FIGS. 1-3, illustrating the occurrence of thermally-induced waveguiding upon application of an energizing current along the injection stripe of the device;

FIG. 5 illustrates an initial configuration of an edge-emitting semiconductor laser formed in accordance with the present disclosure, including the formation of a complete p-type waveguiding layer and p-type cladding layer above the active region;

FIG. 6 shows a following step in a fabrication process of the disclosed laser structure, illustrating the removal of a portion of the active region and overlying waveguiding and cladding layers along the front facet to prepare for the formation of a non-absorbing mirror structure at the front facet;

FIG. 7 illustrates a subsequent configuration of the disclosed edge-emitting semiconductor laser, including an epitaxial growth of a second waveguiding layer and a second cladding layer, the terminal portions of these layers forming the non-absorbing mirror structure;

FIG. 8 shows the refractive index profile and associated mode intensity for an interior portion of the disclosed semiconductor laser that includes the active region (i.e., an “unetched” portion of the laser, also referred to as “epi I”);

FIG. 9 shows the refractive index profile and mode intensity for an end portion of the disclosed semiconductor laser associated with the region where the non-absorbing mirror structure is formed (i.e., the “etched” portion of the laser, also referred to as “epi II”);

FIG. 10 is a simulation of fundamental mode propagation within a prior art structure, illustrating a poor optical coupling between an interior portion and the associated non-absorbing mirror structure;

FIG. 11 is a simulation of the operation of a semiconductor laser with a double waveguide structure as described in the present disclosure, showing a high coupling efficiency between the first (active) waveguiding layer in the interior portion of the device and the second (passive) waveguiding layer in the non-absorbing mirror structure along the front facet of the disclosed laser;

FIG. 12 is an isometric view of a semiconductor laser formed in accordance with the teachings of the present disclosure, illustrating the use of the double waveguiding arrangement to alter lateral confinement of the propagating optical modes;

FIG. 13 contains a set of plots associated with the device of FIG. 12, illustrating the results of using a double waveguide configuration that exhibits a positive change in effective refractive index with respect to the central guiding area of the device; and

FIG. 14 contains another set of plots associated with the device of FIG. 12, in this case where the properties of the double waveguide are controlled to exhibit a negative step change in effective refractive index with respect to the central guiding area.

### DETAILED DESCRIPTION

The principles of the present disclosure may be best understood by comparing its technical details to that of a conventional prior art semiconductor laser formed to include a non-absorbing mirror along a front (emitting) and rear facet. FIG. 1 is an illustration of an intermediate step in the process of fabricating a prior art edge-emitting semiconductor laser. For the purposes of discussion, FIGS. 1-3 are longitudinal views of the laser device, emitting light output in the direction of the arrow (i.e., exiting a front facet of the device structure).

As shown, prior art semiconductor laser 1 comprises a substrate 2, upon which is grown (or deposited) a first cladding layer 3. In most cases, the semiconductor laser utilizes an n-type substrate, with first cladding layer 3 being an n-type material that is epitaxially grown over the exposed top surface of substrate 2. An n-type waveguiding layer 4 (having a higher refractive index value than n-type cladding layer 3) is next formed, as shown, and an active region 5 is disposed to cover the exposed upper surface of n-type waveguiding layer 4. Active region 5 may comprise any type of configuration well-known in the art to impart gain to a propagating optical signal, such as one or more quantum wells (or similar quantum configurations and the like. Following the creation of active region 5, an initial thickness t of a p-type waveguiding layer 6 is formed to cover active region 5 (also referred to as layer 6-1 for reasons apparent below). A front facet 7F of laser 1 is defined along the right-hand edge of the depicted arrangement of FIG. 1, with an emitted lightwave propagating along the longitudinal direction as shown.

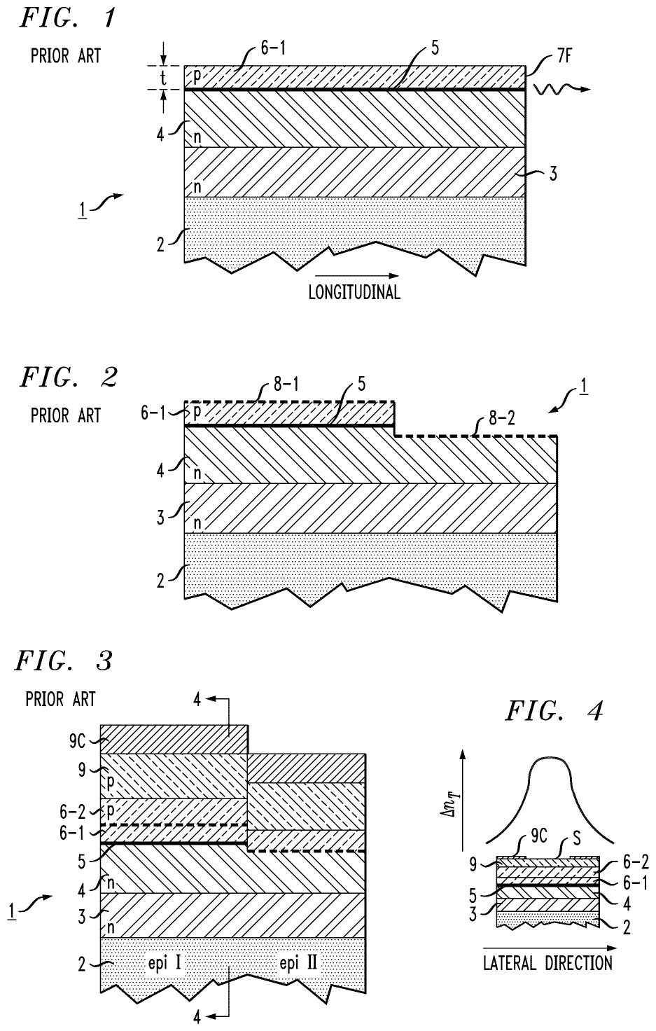

A following step in a prior art process of minimizing facet degradation, as shown in FIG. 2, is to etch away active region 5 and p-type cladding layer 6-1 in the vicinity of facet 7F. The resulting etched structure as shown in FIG. 2 includes an interior step at the location where active region 5 now terminates at a location that is recessed with respect to the location of front facet 7F. The upper surface of the etched structure as shown in FIG. 2 is defined as a regrowth interface 8 (over which additional epitaxial layers will be formed). In this particular structure, regrowth interface 8 is shown as including a first regrowth interface 8-1 section (the unetched top surface of p-type cladding layer 6-1), and a second regrowth interface section 8-2 over the exposed surface of n-type waveguiding layer 4.

Subsequent steps in the prior art fabrication process are shown in FIG. 3, including a growth of epitaxial material (p-type) over regrowth interface sections 8-1 and 8-2. The initial growth step is used to supply the remaining desired thickness for p-type waveguiding layer 6 (the additional waveguiding sub-layer denoted as 6-2 in FIG. 3), where the combined thickness of layers 6-1 and 6-2 create a desired thickness for the p-type waveguiding structure. A p-type cladding layer 9 is then epitaxially grown over p-type waveguiding layer 6 (with an electrical contact layer 9C formed as the top layer of the structure). The combination of waveguiding sub-layer 6-2 and cladding layer 9 within the end portions of the structure create a non-absorbing mirror configuration between the termination of active region 5 and front facet 7F, which will support the continued propagation of the generated laser emission, but not impart any additional energy to the beam.

As mentioned above, the vertical separation between active region 5 and regrowth interface 8 is a significant factor in device performance. That is, depending on the position of regrowth interface 8, either coupling efficiency between unetched epi I and etched epi II portions of the laser structure is low, or defects possibly generated at the regrowth interface during the overgrowth step result in a high level of absorption of the propagating mode and the possibility of COD.

Additionally, it is known that the operation of edge-emitting semiconductor lasers under the conditions required to generate high levels of output power require a significant amount of injection current. Reference is made to prior art FIG. 4, which is an end-view taken along line 4-4 of FIG. 3. During the operation of laser device 1, a current is injected at a defined location along stripe location S, and results in locally elevating the temperature within the area below the injection stripe. The refractive index in this area is elevated as well, creating a thermally-induced waveguide structure Δnτ (as shown in FIG. 4). The thermally-induced waveguide is capable of supporting several unwanted lateral modes.

In accordance with the principles of this disclosure, an improvement in device performance, in terms of both efficient mode coupling and reduction of thermally-induced waveguides, is provided by including an additional p-type waveguide/cladding structure (i.e., “double waveguide”) that functions to shift the regrowth interface away from the propagating optical mode. The double waveguide configuration has been found to improve the coupling efficiency between the active region and the non-absorbing mirror (i.e., epi I and epi II), with the inclusion of the additional waveguiding and cladding layers providing the ability to individually tailor the vertical profile within the body of the laser (epi I) versus the profile at the facets (e.g., epi II region).

FIGS. 5-7 illustrate a series of fabrication steps that may be used to add a second (passive) p-type waveguiding layer and associated cladding layer into an edge-emitting semiconductor laser structure in a manner that provides the desired non-absorbing mirror feature along the facet(s) without experiencing the drop in coupling efficiency (or increase in COD) found in prior art devices. FIG. 5 illustrates a portion of an edge-emitting semiconductor laser 10 at an intermediate step in the fabrication process. Similar to the discussion of prior art laser 1, edge-emitting semiconductor laser 10 is shown as including a substrate (n-type) 12 upon which an n-type cladding layer 14 and n-type waveguiding layer 16 are formed. Active region 18 is next formed on the exposed top major surface of n-type waveguiding layer 16, where active region 18 may comprise any one of several known types of arrangements (quantum wells, dots, wires, or the like). Also shown in FIG. 5 is the formation of a first p-type waveguiding layer 20 over active region 18, with a first p-type cladding layer 22 then formed to cover first p-type waveguiding layer 20. First p-type waveguiding layer 20 may also be referred to at times hereafter as “active” waveguiding layer 20. The structure as shown in FIG. 5 is defined as including a front (emitting) facet 24F.

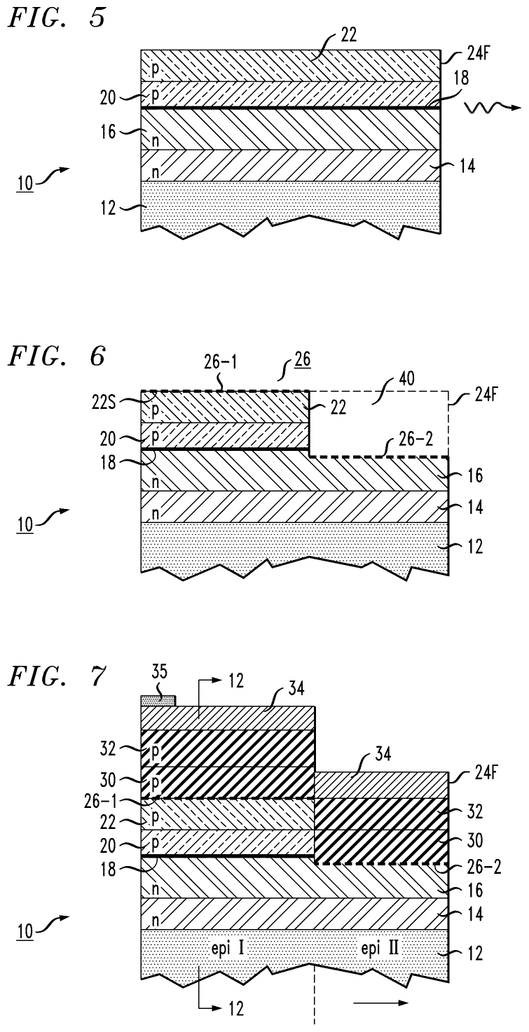

It is at this point in the fabrication that an etching process is performed to define the region where the non-absorbing mirror is to be located at front facet 24F. This is shown in FIG. 6, which illustrates the removal of active region 18, first waveguiding layer 20 and first cladding layer 22 along a recessed longitudinal extent from device front facet 24F (i.e., from an end portion of the laser structure). This step results in having active region 18 terminate within an interior location of laser 10, reducing the opportunity for damage to laser facet 24F from the high temperatures associated with active region 18.

Well-known patterning and etching processes may be used to create the structure as shown. A regrowth interface 26 is illustrated in this structure as including a first section 26-1 along a top surface 22S of unetched p-type cladding layer 22, and a second section 26-2 extending over a surface 16S of n-type waveguiding layer 16 that has been exposed during the etching process. The structure as shown in FIG. 6 is hereafter defined as including an “unetched epitaxial region I” (or simply “epi I”) and an “etched epitaxial region II” (or simply “epi II”). A non-absorbing mirror structure M is defined within epi II.

FIG. 7 illustrates a following step of forming a second p-type waveguiding layer 30 and a following p-type cladding layer 32 over regrowth interface 26. In particular, second layers 30 and 32 are grown over both sections of regrowth interface 26-1 and 26-2. A contact layer 34 is then formed over second p-type cladding layer 32. While not specifically shown in detail, the current injected to initiate lasing is applied at a defined location of central stripe 35 formed along contact layer 34. The structure as depicted in FIG. 7 is considered as one example of a double waveguide laser structure formed in accordance with the present disclosure.

As will be discussed in detail below, the complete stack of first and second waveguiding and cladding layers within the epi I portion of laser structure 10 allows for control of the positioning of regrowth interface 26-1 with respect to the propagating mode. In particular, the inclusion of the second (passive) waveguide and cladding layers allows for the regrowth interface to shift upward to the top surface of first p-type cladding layer 22. The epi II portion of the laser structure comprises the stack of n-type cladding layer 14 and n-type waveguiding layer 16 with second waveguiding and cladding layers 30, 32. Inasmuch as active region 18 is not present in the epi II portion of the structure (i.e., second waveguiding layer 30 is referred to as a “passive waveguide”), the formed non-absorbing mirror area M supports the propagation of the generated laser emission toward front facet 24F, but does not impart any additional gain to the signal.

In accordance with the principles of the present disclosure, the thicknesses and compositions of first p-type waveguiding layer 20 and associated p-type cladding layer 22 are preferably selected such that a minimum value (i.e., “null”) of the propagating longitudinal optical mode will align with the location of regrowth interface 26-1.

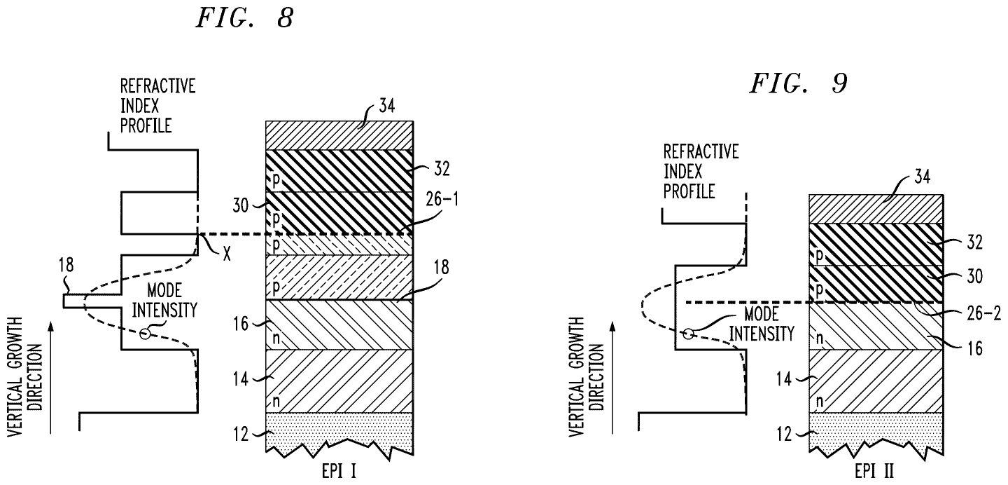

FIG. 8 contains an example refractive index profile and associated optical mode intensity as related to the vertical design configuration of an interior portion of semiconductor laser 10 (that is, the epi I section as defined above). The optical mode is illustrated as a dashed line in FIG. 8. In this particular example, the peak of the optical mode is shown as coinciding with active region 18. However, it is to be noted that the overlap of the optical mode peak with active region 18 may not necessarily be the case for state-of-the-art vertical high-power laser cavities.

By virtue of controlling the composition and thicknesses of first p-type waveguiding layer 20 and first p-type cladding layer 22 in the manner discussed above in association with FIG. 7, the resultant refractive index profile as shown in FIG. 8 is such that the optical mode is essentially zero at regrowth interface 26-1, as indicated by the “X” in FIG. 8. This also confirms the design objective of confining the propagation of the optical mode within first p-type waveguiding layer 20, as described above (and away from regrowth interface 26). Therefore, by creating a null in the optical mode at the regrowth interface, the optical mode will remain confined within n-type waveguiding layer 16 and first p-type waveguiding layer 20.

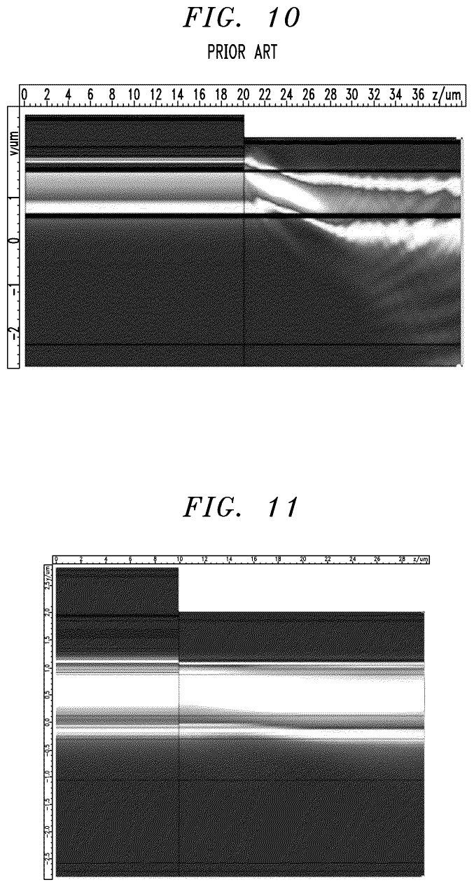

By appropriately choosing a composition and thickness for second passive p-type waveguiding layer 30 and cladding layer 32, the propagating mode will be efficiently coupled into second, passive p-type waveguiding layer 30 (i.e., epi II). In particular, FIG. 9 contains a refractive index profile and related optical mode field (dashed line) for the epi II region of edge-emitting double waveguide semiconductor laser 10. The properties of passive p-type waveguiding layer 30 and second p-type cladding layer 32 are selected to ensure good coupling efficiency between the two sections of the laser structure (i.e., between epi I and epi II). As a result, a relatively high optical output power may exit through non-absorbing mirror M, in contrast to the somewhat weaker outputs found in some prior art non-absorbing mirror configurations.

Confirmation of the improvements in laser operation associated with the disclosed double waveguide structure may be found by comparing the simulation diagrams of FIGS. 10 and 11. FIG. 10 is associated with a prior art device (such as that depicted in FIGS. 1-4) and shows a relatively low coupling efficiency between the unetched epi I and etched epi II portions of the laser structure. In contrast, the simulation of FIG. 11 (associated with the disclosed double waveguide arrangement) exhibits good coupling efficiency; indeed, close to 100% of the propagating optical mode is coupled into the passive waveguide within the non-absorbing mirror structure.

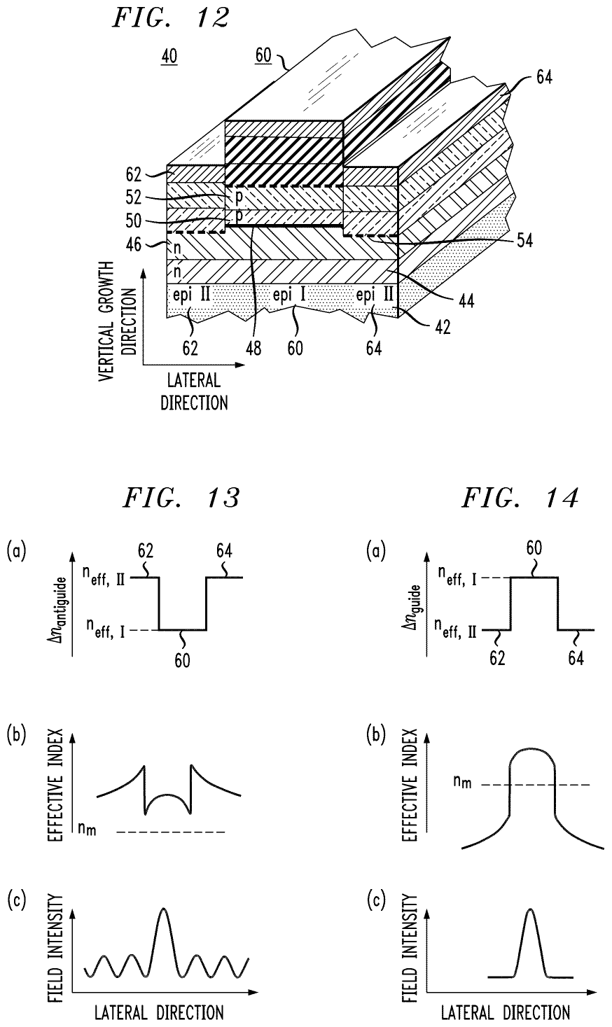

The disclosed double waveguide edge-emitting laser may also be configured, as mentioned above, to have the form of a pair of lateral side regions (of epi II form) disposed on either side of a central injection stripe (epi I) of an edge-emitting laser structure. FIG. 12 illustrates an example of a double waveguide laser structure 40 formed in accordance with this example to include a central injection stripe (i.e., central guiding area) 60, with a pair of double waveguide structures 62, 64 disposed along the opposing lateral sides of central guiding area 60.

Similar to double waveguide laser structure 10 described above, double waveguide laser structure 40 is an edge-emitting device and includes n-type and p-type waveguiding and cladding layers formed (grown) on a semiconductor substrate of appropriate material. In this particular illustration, double waveguide laser 40 comprises a substrate 42, with an n-type cladding layer 44 and n-type waveguiding layer 46 formed on substrate 42. An active region 48 is formed on n-type waveguiding layer 46. Also similar to the above-described double waveguide laser structure 10, a first p-type waveguiding layer 50 and a first p-type cladding layer 52 are formed over active region 48.

For this particular arrangement, opposing lateral sides of the created structure are then etched in a known manner to remove active region 48, first waveguiding layer 50 and first cladding layer 52. A regrowth interface 54 defines this etched surface, with a following second p-type waveguiding layer 56 and second p-type cladding layer 58 grown over interface 54. The resultant double waveguiding structure, as shown in FIG. 12, contains the pair of lateral passive structures (epi II) of second p-type waveguiding and cladding layers 56, 58 and the central complete “stack” of both first p-type waveguiding and cladding layers 50, 52 and second p-type waveguiding and cladding layers 56, 58.

The inclusion of the double waveguide structure along the lateral sides of the laser structure and extending longitudinally along its optical axis has been found to be able to control the properties of thermally-induced waveguides that could otherwise support the propagating of unwanted, higher-order modes. Recall from the discussion of prior art FIG. 4 that the presence of high current levels within the injection stripe are known to elevate the temperature and refractive index profiles of semiconductor layers in proximity to the current flow. The thermally-induced waveguides created by this temperature differential are known to support lateral modes that negatively impact the performance of the laser device (even more so as current levels increase and the temperature/refractive index difference increases).

It is proposed that the inclusion of double waveguide passive sections 62, 64 along opposing sides of a central guiding area 60 of edge-emitting semiconductor laser 40 provides a mechanism that is able to control the optical properties impacted by the elevated temperature associated with the injection current. In particular passive waveguiding/cladding layers 56, 58 function to shift the position of any propagating lateral modes (similar to the shifting provided to the longitudinal mode between epi I and epi ii) to minimize the effects/appearance of these lateral modes.

The formation of semiconductor laser 40 as shown in FIG. 12 to include double waveguide passive sections 62, 64 has been found to suppress the excitation of unwanted lateral modes. The thickness and composition of passive waveguiding and cladding layers 62, 64 may be adjusted to provide the necessary amount of mode suppression that is desired. Indeed, the composition of these layers may be such as to create either a “positive” index step change with respect to central guiding area 60, or a “negative” index step change with respect to guiding area 60.

FIG. 13 includes plots illustrating the impact of a positive step change in refractive index between the epi II and epi I regions of double waveguide laser structure 40. Plot (a) illustrates the positive step change itself, where the effective refractive index of epi II (i.e., regions 62, 64) is configured to be greater than the effective refractive index of epi I (i.e., central guiding area 60). As shown, this positive step relationship is referred to as an “antiguiding” structure and the difference in effective refractive index is defined as Δn_{antiguide}. Upon the energizing of a laser with this positive step relationship, the elevated temperature experienced within central guiding area 60 increases its effective refractive index as in the prior art laser (compare FIG. 4), but the additional effective refractive index change of the antiguide results in an elevation of the effective index in regions 62, 64, as depicted in plot (b) of FIG. 13. A higher-order lateral mode may have a modal index nm that lies below the effective index of the center and side regions and is suppressed. Plot (c) illustrates the intensity of the unguided lateral mode that experiences high radiation losses.

FIG. 14 includes plots similar to those of FIG. 13, except in this case for negative step change in effective refractive index between epi II and epi I. The resultant change in effective refractive index across this boundary is defined as Δn_{guide}. In this case, the example lateral mode with modal index nm remains guided within central active area 60, as shown by the position of mode index nm in plot (b) of FIG. 14, where the specific properties of passive sections 62, 64 may be tailored to control the number of excited lateral modes contributing to the propagating field. For example, the value of Δn_{guide} may be used to stabilize the near-field width of the longitudinal mode. Plot (c) of FIG. 14 shows the intensity of the lateral mode associated with this Δn_{guide} relationship.

The disclosed laser structure may be embodied in other specific forms without departing from its spirit or essential characteristics. The described embodiments are to be considered in all respects only as illustrative, and not restrictive. The scope of the present disclosure is, therefore, indicated by the appended claims rather than by the foregoing description. All changes that come within the meaning and range of equivalency of the claims are to be embraced within their scope.

What is claimed is:

1. An edge-emitting semiconductor laser comprising:
a semiconductor substrate;
a cladding layer of a first conductivity type formed on the semiconductor substrate;
a waveguiding layer of the first conductivity type formed on the cladding layer;
an active region disposed over a defined region of the waveguiding layer;
a first waveguiding layer of a second, opposing conductivity type formed over the active region;
a first cladding layer of the second conductivity type formed over the first waveguiding layer, where defined areas of the combination of the active region, the first waveguiding layer and the first cladding layer have been removed and defining a regrowth interface along surfaces of the waveguiding layer of the first conductivity type exposed by the removal;
a second waveguiding layer of the second conductivity type formed over the regrowth interface; and
a second cladding layer of the second conductivity type formed over the second waveguiding layer of the second conductivity type, wherein the composition and thicknesses of the first waveguiding and cladding layers of the second conductivity type are selected to create a defined separation between a propagating longitudinal optical mode and the regrowth interface.

2. The edge-emitting laser as defined in claim 1, wherein the defined area of removal for the active region, the first waveguiding layer and the first cladding layer includes a recessed area along a front facet of the edge-emitting laser, the formed second guiding and cladding layers formed in the recessed area creating a non-absorbing mirror for the edge-emitting laser.

3. The edge-emitting laser as defined in claim 2 wherein a composition and thickness of the first waveguiding layer of the second conductivity type and the first cladding layer of the second conductivity type are selected such that an intensity value of a propagating longitudinal mode that coincides with the location of the regrowth interface is close to zero.

4. The edge-emitting laser as defined in claim 1, wherein the defined area of removal for the active region, the first waveguiding layer, and the first cladding layer includes opposing lateral side areas of the edge-emitting laser in a region proximate to a current injection region, forming a central injection stripe and guiding area, the combination of the second waveguiding layer and the second cladding layer formed along the opposing lateral side areas to provide passive current confinement and lateral mode suppression.

5. The edge-emitting laser as defined in claim 4, wherein the composition and thickness of the second waveguiding and cladding layers are selected with respect to the composition and thickness of the first waveguiding and cladding layers such that the refractive index of the second waveguiding layer is greater than that of the first waveguiding layer, forming an antiguiding laser structure in the presence of thermally-induced waveguides.

6. The edge-emitting laser as defined in claim 4, wherein the composition and thickness of the second waveguiding and cladding layers are selected with respect to the composition and thickness of the first waveguiding and cladding layers such that the refractive index of the second waveguiding layer is less than that of the first waveguiding layer to form a controlled guiding of lateral modes in the presence of thermally-induced waveguides.

7. A method of making a laser structure, comprising:
providing a semiconductor substrate of a first conductivity type;
forming, in sequence, a cladding layer of the first conductivity type and a waveguiding layer of the first conductivity type on the semiconductor substrate;
forming an active region across a top surface of the first conductivity type waveguiding layer;
forming, in sequence, a first waveguiding layer of a second, opposing conductivity type and a first cladding layer of the second, opposing conductivity type over the active region, the formed configuration defined as having a front facet and an opposing rear facet wherein upon activation an optical beam is emitted at least through the front facet;
removing a combination of the active region, the first waveguiding layer and the first cladding layer from a portion of the formed configuration, an exposed surface formed by the removal defined as a regrowth interface; and
forming, in sequence, a second waveguiding layer of the second conductivity type and a second cladding layer of the second conductivity type over the regrowth interface, selected to create a defined separation between a propagating longitudinal optical mode and the regrowth interface.

8. The method as defined in claim 7, wherein in performing the removing step, an end portion of the combination of the active region, the first waveguiding layer, and the first cladding layer proximate to a front facet of the laser structure is removed, creating a non-absorbing mirror during the step of forming, in sequence, the second waveguiding layer and second cladding layer of the second conductivity type.

9. The method as defined in claim 7, wherein in performing the removing step, side portions of the combination of the active region, the first waveguiding layer, and the first cladding layer proximate to a current injection region of the laser structure is removed, creating a current confinement and lateral mode suppression structure.

10. An edge-emitting semiconductor laser comprising:
a semiconductor substrate;
a cladding layer of a first conductivity type formed on the semiconductor substrate;
a waveguiding layer of the first conductivity type formed on the cladding layer;
an active region disposed over a defined region of the waveguiding layer;
a first waveguiding layer of a second, opposing conductivity type formed over the active region;
a first cladding layer of the second conductivity type formed over the first waveguiding layer, where defined areas of the combination of the active region, the first waveguiding layer and the first cladding layer have been removed and defining a regrowth interface along surfaces of the waveguiding layer of the first conductivity type exposed by the removal;
a second waveguiding layer of the second conductivity type formed over the regrowth interface; and
a second cladding layer of the second conductivity type formed over the second waveguiding layer of the second conductivity type, wherein the composition and thicknesses of the first waveguiding and cladding layers of the second conductivity type are selected to create a defined separation between a propagating longitudinal optical mode and the regrowth interface, including
a first defined area of removal for the active region, the first waveguiding layer and the first cladding layer includes a recessed area along a front facet of the edge-emitting laser, the formed second guiding and cladding layers formed in the recessed area creating a non-absorbing mirror for the edge-emitting laser; and
a second defined area of removal for the active region, the first waveguiding layer, and the first cladding layers including opposing lateral side areas of the edge-emitting laser in a region proximate to a current injection region, forming a central injection stripe and guiding area, the combination of the second waveguiding and cladding layers of the second conductivity type formed along the opposing lateral side areas to provide passive current confinement and lateral mode suppression.
